(19) United States
(12) Patent Application Publication
(10) Pub. No.: US 2020/0312775 A1
(43) Pub. Date: Oct. 1, 2020

(54) SEMICONDUCTOR DEVICE HAVING A BARRIER LAYER MADE OF TWO DIMENSIONAL MATERIALS

(71) Applicant: GLOBALFOUNDRIES INC., GRAND CAYMAN (KY)

(72) Inventors: RINUS TEK PO LEE, Ballston Lake, NY (US); FUAD AL-AMOODY, Rexford, NY (US); ASLI SIRMAN, Malta, NY (US); JOSEPH KYALO KASSIM, Rio Rancho, NM (US); HUI ZANG, Guilderland, NY (US); BHARAT V. KRISHNAN, Mechanicville, NY (US)

(21) Appl. No.: 16/368,836

(22) Filed: Mar. 28, 2019

(51) Int. Cl. H01L 23/532; H01L 23/522; H01L 21/768

(52) U.S. Cl. CPC H01L 23/53238; H01L 21/76847; H01L 21/76802; H01L 23/5226

(57) ABSTRACT

A semiconductor device structure is provided that includes a dielectric layer and a barrier layer having at least two layers of two dimensional materials on the dielectric layer, wherein each layer is made of a different two dimensional material.

### FIELD OF THE INVENTION

The present disclosure relates to semiconductor devices and the manufacturing thereof, and more specifically, to the use of two dimensional materials as a barrier layer in semiconductor devices.

### BACKGROUND

As feature sizes in semiconductor integrated circuits (ICs) continue to shrink, it is essential to scale down the interconnect structures as well. Copper (Cu) is a widely used metal for semiconductor interconnects. The main challenges in scaling down Cu technology are in the metal fill process, compensating for the decreased metal fill area and the potential for scattering in the interconnect lines. Accordingly, as interconnect features shrink, it is essential to scale down the barrier layer thickness to allow for sufficient metal fill area.

A thick barrier layer will reduce the size of the metal fill area, leading to higher sheet resistance in the narrow interconnect lines. In order for Cu technology to scale below 20 nm linewidth, it is essential to scale down the barrier layer thickness to below 2.5 nm, while maintaining barrier integrity. To date, barrier layer thickness has not been scaled below 2.5 nm, as it is difficult to have a thin barrier layer with sufficient barrier integrity, because, below 2.5 nm, a conventional TaN barrier layer will break down.

“Two dimensional materials” are crystalline materials that can have a thickness of a few nanometers or less. Electrons in these materials are free to move in the two-dimensional plane, but their restricted motion in the third direction is a result of their unique quantum mechanical property. The thickness of a monolayer of these materials can be in the range of 0.3 to 0.5 nm (i.e., 3 to 5 Å). However, one of the main challenges in using two dimensional materials as a barrier layer is the presence of pinholes that will eventually lead to early failure of the device, because it is difficult to grow a defect-free, monolayer of a two dimensional material.

### SUMMARY

In one aspect of the present disclosure, there is provided a semiconductor device structure having a dielectric layer and a barrier layer having at least two layers of two dimensional materials on the dielectric layer, wherein each layer is made of a different two dimensional material.

In another embodiment, there is provided a semiconductor device structure that includes a semiconductor substrate and a dielectric layer placed over the semiconductor substrate, with a trench having sidewalls and a bottom formed in the dielectric material and a nano-laminate barrier layer comprising at least two layers of two dimensional materials covering the sidewalls and the bottom of the trench, wherein each layer is made of a different two dimensional material.

In another aspect of the present disclosure, a method is provided to form a semiconductor device structure by providing a dielectric layer and forming an opening in the dielectric layer, and depositing a barrier layer having at least two layers of two dimensional materials on the dielectric layer, wherein each layer is made of a different two dimensional material.

### BRIEF DESCRIPTION OF THE DRAWINGS

The present disclosure may be understood by reference to the following description taking in conjunction with the accompanying drawings.

FIG. 1 is a schematic cross-sectional view of a semiconductor device structure in accordance with some embodiments of the present disclosure.

FIGS. 2A-2F are schematic cross-sectional views of various stages of a process for forming a semiconductor device structure in accordance with some embodiments of the present disclosure.

FIGS. 3A-3D are schematic cross-sectional views of various stages of a process for forming a semiconductor device structure in accordance with some embodiments of the present disclosure.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

### DETAILED DESCRIPTION

The semiconductor device structure provided in the present disclosure advantageously overcomes a challenge resulting from scaling. For semiconductor devices structures with interconnects, a barrier layer feature of the present disclosure comprising a nano-laminate of different two dimensional materials is able to overcome the problems associated with pinhole formation, which will lead to increased reliability (e.g., improved Time Dependent Dielectric Breakdown or “TDDB” reliability) and better resistance to metal (e.g., Cu, Co or W) diffusion. In addition, as two dimensional materials are ultra-thin monolayers (i.e., thicknesses in the range of 3 to 5 Å), the use of these materials as barrier layer enables scaling down of the barrier layer thickness to 2.5 nm and below, which allows a larger volume of metal fill in narrow interconnect features and a lower sheet resistance.

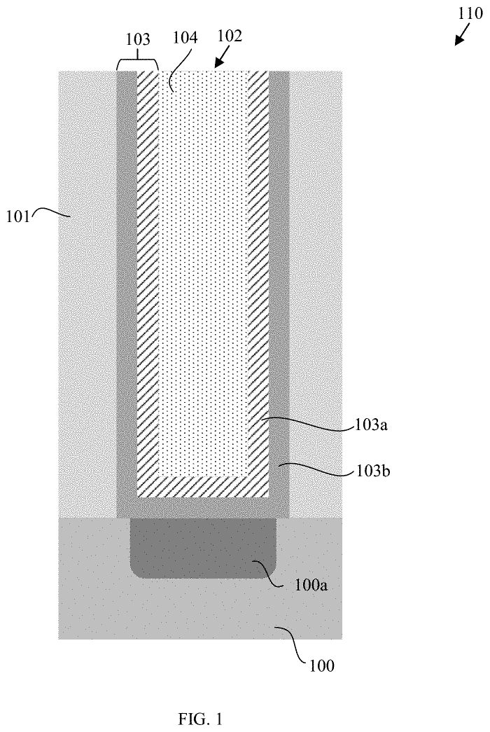

Referring to FIG. 1, a schematic cross-sectional view of a semiconductor device structure 110 with a nano-laminate barrier layer 103 using single layers of different two dimensional materials 103a-103b in accordance with some embodiments of the present disclosure is presented. The semiconductor device structure 110 comprises a dielectric layer 101, and a barrier layer 103 having at least two layers of two dimensional materials on the dielectric layer, wherein the layers 103a and 103b are nano-laminates made of different two dimensional materials.

The barrier layer 103 may be made of several layers of two dimensional materials, with each layer being a different two dimensional material. The preferred number of layers of two dimensional materials is in the range of two to six.

In a first embodiment, the two dimensional material comprises transition metal dichalcogenide (MX₂) materials, wherein M is a transition metal selected from the group consisting of Sc, Y, La, Ac, Ti, Zr, Hf, Rf, V, Nb, Ta, Fa, Cr, Mo, W, Mn, Tc, Re, Fe, Ru, Os, Co, Rh, Ir, Ni, Pb, Pt, Cu, Ag, Au, Zn, Cd, Hg, and wherein X is a chalcogen selected from the group consisting of S, Se and Te.

In a second embodiment, the two dimensional material comprises h-BN, graphene, borophene, silicence, phosphorene and boroncarbonitrides, or a combination thereof.

In an exemplary embodiment, the barrier layer 103 is a nano-laminate structure having a total thickness of less than 1 nm. The nano-laminate structure comprises at least two layers of different two dimensional materials in order to allow for greater scalability. A trench 102 having sidewalls and a bottom is formed in the dielectric material 101 and the barrier layer 103 is covering the sidewalls and the bottom of the trench 102. A metal 104 fills the trench 102 over the barrier layer 103 at the bottom of the trench 102.

In one embodiment, the dielectric layer 101 of the semiconductor device structure 110 is formed over a semiconductor substrate 100 having a source/drain element 100a, and the barrier layer 103 at the bottom of the trench 102 is formed at a top surface of the semiconductor substrate 100. Each layer of two dimensional material (103a and 103b) is between 3 to 5 Å thick.

In an alternative embodiment, a semiconductor device structure 110 having features of the present invention comprises a semiconductor substrate 100 and a dielectric layer 101 placed over the semiconductor substrate 100, with a trench 102 having sidewalls and a bottom formed in the dielectric material 101, and a nano-laminate barrier layer 103 comprising at least two layers of two dimensional materials covering the sidewalls and bottom of the trench 102, wherein each layer (103a and 103b) is made of a different two dimensional material.

In some embodiments, due to the laminate structure comprising layers of different two dimensional materials, pinhole formation is avoided and barrier layer integrity is improved. This results in increased reliability (e.g., improved TDDB reliability) and better resistance to metal (e.g., Cu, Co or W) diffusion. In addition, as two dimensional materials are ultra-thin layers (i.e., The thickness of a monolayer of these materials is in the range of 3 to 5 Å), the use of these materials as barrier layer enables scaling down of the barrier layer thickness to 1 nm and below. This allows a larger volume fraction of metal fill in narrow interconnect features leading to lower sheet resistance.

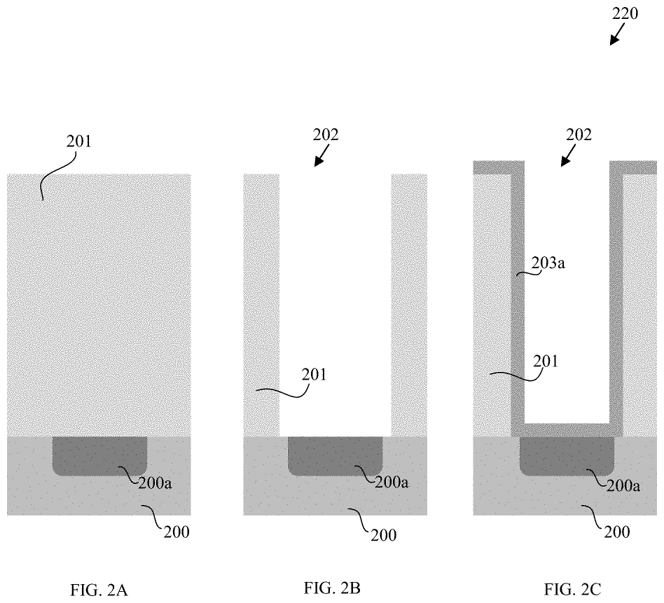

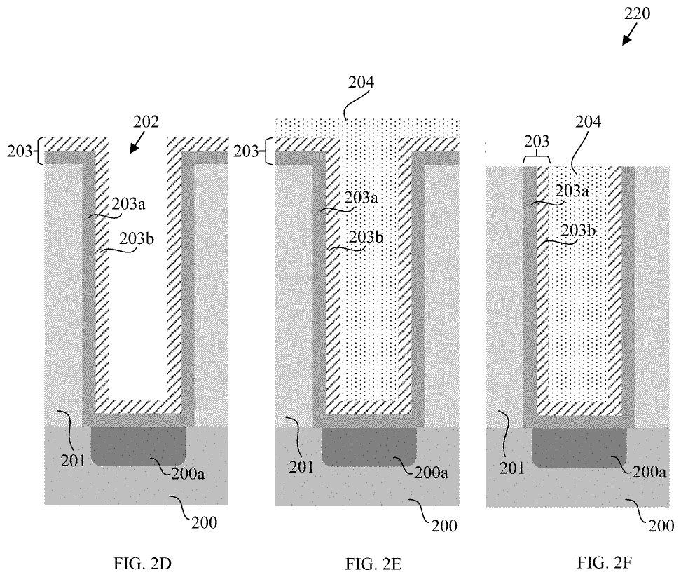

The FIGS. 2A to 2F show the intermediate embodiments of the present disclosure for a semiconductor device structure 220. Referring to FIG. 2A, the semiconductor device structure 220 includes a dielectric layer 201. In some embodiments, the dielectric layer 201 is an interlayer dielectric (ILD). In other embodiments, the dielectric layer 201 is made of silicon oxide, silicon oxynitride, borosilicate glass (BSG), phosphoric silicate glass (PSG), fluorinated silicate glass (FSG), low dielectric constant (low-k) material, another suitable material or a combination thereof. In further embodiments, the dielectric layer 201 includes multiple sub-layers. The dielectric layer 201 may be deposited using a chemical vapour deposition (CVD) process, an atomic layer deposition (ALD) process, a spin-on process, another applicable process, or a combination thereof.

Referring to FIG. 2B, an opening 202 is formed in the dielectric layer 201 by patterning the dielectric layer 201. In some embodiments, the formation of the opening 202 may involve multiple photolithography processes and etching processes. In accordance with the embodiments of the present disclosure, the opening 202 may be a trench, contact or via.

Referring to FIG. 2C, a layer of two dimensional material 203a is deposited on the dielectric layer 201 and is used as part of a barrier layer to prevent metal diffusion.

In FIG. 2D, another layer of two dimensional material 203b is deposited on the dielectric layer 201. Hence, barrier layer 203 has at least two layers of two dimensional materials (203a and 203b, respectively) on the dielectric layer 201, with each being made of a different two dimensional material. Each layer of two dimensional material (203a and 203b) is formed by an appropriate deposition process (e.g., ALD or CVD). As used herein, the term “deposition” generally refers to the process of placing a material over another material (e.g., a substrate).

In some embodiments, the opening 202 in the dielectric layer 201 is a trench opening having sidewalls and a bottom and the barrier layer is conformally deposited covering the sidewalls and bottom of the trench.

Referring to FIG. 2E, a metal layer 204 is deposited in the trench opening 202 over the barrier layer 203 at the bottom of the trench. The metal layer 204 may be made of Cu, Co, W, or other suitable metal materials, or a combination thereof. Possible fabrication processes for the metal layer 204 are electroplating, CVD, physical vapour deposition (PVD), electroless plating, ALD, another suitable process, or a combination thereof.

In one alternative embodiment, the dielectric layer 201 is deposited over a semiconductor substrate 200 having a source/drain element 200a, wherein the barrier layer 203 at the bottom of the trench 202 is deposited at a top surface of the semiconductor substrate 200.

The semiconductor substrate 200 includes silicon, other elementary semiconductor material, such as germanium or a compound semiconductor. The compound semiconductor may include silicon carbide, gallium arsenide, indium arsenide, indium phosphide, another suitable compound semiconductor, or a combination thereof. The semiconductor substrate 200 may also include a semiconductor-on-insulator (SOI) substrate. The SOI substrate may be fabricated by a separation by implantation of oxygen (SIMOX) process, a wafer bonding process, another applicable method, or a combination thereof.

Referring to FIG. 2F, a planarization process is used to remove portions of the barrier layer 203 and metal layer 204 on the top surface of the semiconductor device structure 220. This final embodiment shown in FIG. 2F has an identical structure to the one shown in FIG. 1.

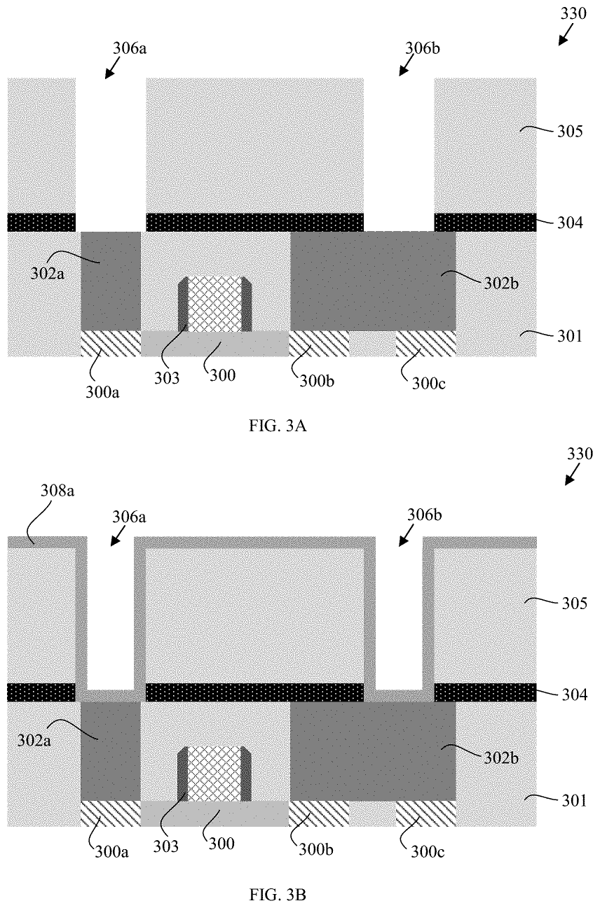

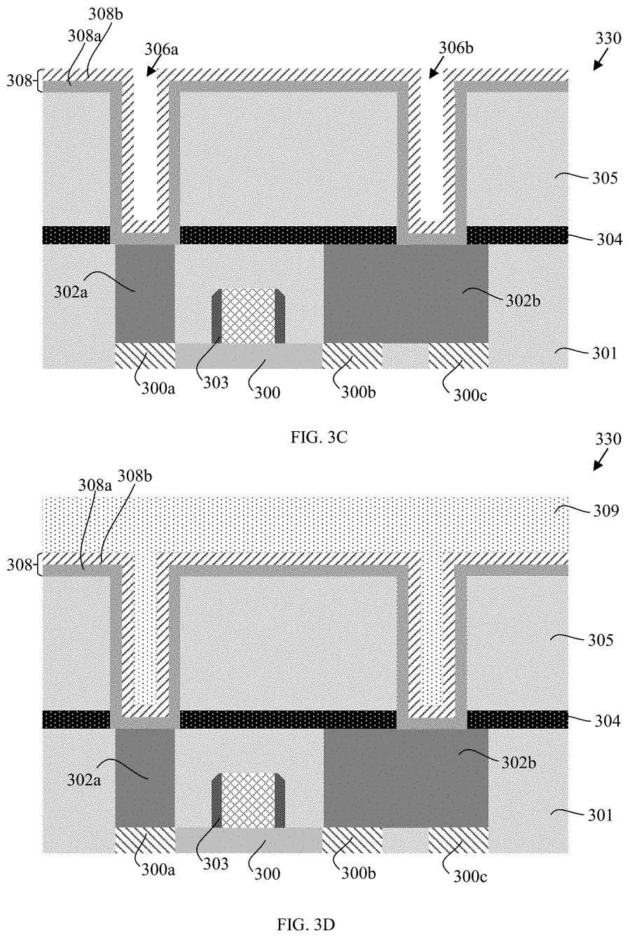

The FIGS. 3A to 3D show the intermediate embodiments of the present disclosure for a semiconductor device structure 330. Referring to FIG. 3A, the semiconductor device structure 330 includes a semiconductor substrate 300, source or drain elements 300a, b and c formed in the semiconductor substrate 300 and a transistor structure 303. In some embodiments, the transistor structure may have a metal gate. The semiconductor device structure 330 may further comprise an etch stop layer 304, which may be made of silicon nitride. The dielectric layers 301 and 305 are interlayer dielectrics (ILDs). The openings 306a and 306b are formed by patterning the dielectric layer 305.

In one embodiment, conductive lines 302a and 302b are formed on the semiconductor device structure 330, and the dielectric layer 305 is deposited over the conductive lines 302a and 302b. The openings 306a and 306b formed in the dielectric layer 305 are via openings, each having a sidewall and a bottom exposing a top surface of the conductive lines 302a and 302b, respectively.

Referring to FIG. 3B, a layer of two dimensional material 308a is deposited on the dielectric layer 305, covering the sidewall and bottom of via openings 306a and 306b.

Referring to FIG. 3C, another layer of two dimensional material 308b is deposited on the dielectric layer 305, covering the sidewall and the bottom of via openings 306a and 306b. Hence, barrier layer 308 has at least two layers of two dimensional materials on the dielectric layer 305, wherein each layer is made of a different two dimensional material. The barrier layer 308 is conformally deposited covering the sidewall and the bottom of via openings 306a and 306b, respectively, and forming interconnect vias in the via openings.

Hence, in one embodiment, a dielectric layer 305 is formed over conductive lines 302a and 302b, via openings 306a and 306b are formed in the dielectric layer 305 and a barrier layer 308 is formed in the via openings 306a and 306b at a top surface of the conductive lines, and interconnect vias are formed in the via openings.

In some embodiments, conductive lines 302a and 302b may be W contacts or interconnect metal lines. In some embodiments, the openings 306a and 306b may be trench openings.

Referring to FIG. 3D, a Cu metal layer 309 is deposited in the openings 306a and 306b covering the barrier layer 308 at the bottom of the openings 306a and 306b. An interconnect metal layer 309 is formed on top of the dielectric layer 305.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of semiconductor devices for integrated circuits are well-known and so, in the interest of brevity, many conventional processes are only mentioned briefly herein or omitted entirely without providing the well-known process details.

As will be readily apparent to those skilled in the art upon a complete reading of the present application, the semiconductor devices and methods disclosed herein may be employed in manufacturing a variety of different integrated circuit products including, but not limited to, Field Effect Transistor (FET) channel devices, photo-detectors and photovoltaic devices.

1. A semiconductor device structure comprising:
a dielectric layer; and
a barrier layer having at least two layers of two dimensional materials on the dielectric layer, wherein each layer is made of a different two dimensional material.

2. The semiconductor device structure of claim 1, wherein the two dimensional material comprises transition metal dichalcogenide (MX₂) materials.

3. The semiconductor device structure of claim 2, wherein the transition metal dichalcogenide (MX₂) materials further comprises M being a transition metal selected from the group consisting of Sc, Y, La, Ac, Ti, Zr, Hf, Rf, V, Nb, Ta, Fa, Cr, Mo, W, Mn, Tc, Re, Fe, Ru, Os, Co, Rh, Ir, Ni, Pb, Pt, Cu, Ag, Au, Zn, Cd, Hg, and X being a chalcogen selected from the group consisting of S, Se and Te.

4. The semiconductor device structure of claim 1, wherein the two dimensional material comprises h-BN, graphene, borophene, silicence, phosphorene and boroncarbonitrides, or a combination thereof.

5. The semiconductor device structure of claim 1, wherein the barrier layer is a nano-laminate structure having a total thickness of less than 1 nm.

6. The semiconductor device structure of claim 1, wherein a trench having sidewalls and a bottom is formed in the dielectric material and the barrier layer is covering the sidewalls and bottom of the trench.

7. The semiconductor device structure of claim 6, wherein a metal fills the trench over the barrier layer at the bottom of the trench.

8. The semiconductor device structure of claim 7 further comprising:
the dielectric layer is formed over a semiconductor substrate having a source/drain element, wherein the barrier layer at the bottom of the trench is formed at a top surface of the semiconductor substrate.

9. The semiconductor device structure of claim 1 further comprising:
the dielectric layer is formed over a conductive line;
a via opening is formed in the dielectric layer and the barrier layer is formed in the via opening at a top surface of the conductive line; and
an interconnect via is formed in the via opening.

10. The semiconductor device structure of claim 1, wherein each layer of two dimensional material is between 3 to 5 Å thick.

11. A semiconductor device structure comprising:
a semiconductor substrate;
a dielectric layer over the semiconductor substrate;
a trench having sidewalls and a bottom formed in the dielectric material; and
a nano-laminate barrier layer comprising at least two layers of two dimensional materials covering the sidewalls and bottom of the trench,
wherein each layer is made of a different two dimensional material.

12. The semiconductor device structure of claim 11, wherein the two dimensional material comprises transition metal dichalcogenide (MX₂) materials.

13. The semiconductor device structure of claim 11, wherein the two dimensional material comprises h-BN, graphene, borophene, silicence, phosphorene and boroncarbonitrides, or a combination thereof.

14. A method to form a semiconductor device structure comprising:
providing a dielectric layer;
forming an opening in the dielectric layer;
depositing a barrier layer having at least two layers of two dimensional materials on the dielectric layer, wherein each layer is made of a different two dimensional material.

15. The method according to claim 14, wherein a layer of two dimensional material is deposited using atomic layer deposition process.

16. The method according to claim 14, wherein a layer of two dimensional material is deposited using chemical vapour deposition process.

17. The method according to claim 14, wherein the opening in the dielectric layer is a trench opening having sidewalls and a bottom and the barrier layer is conformally deposited covering the sidewalls and the bottom of the trench.

18. The method according to claim 17 further comprising depositing a metal in the trench opening over the barrier layer at the bottom of the trench.

19. The method according to claim 17 further comprising depositing the dielectric layer over a semiconductor substrate having a source/drain element, wherein the barrier layer at the bottom of the trench is deposited at a top surface of the semiconductor substrate.

20. The method according to claim 14 further comprising:
forming a conductive line on the semiconductor device structure, wherein the dielectric layer is deposited over the conductive line and the opening formed in the dielectric layer is a via opening having a sidewall and a bottom exposing a top surface of the conductive line;
the barrier layer is conformally deposited covering the sidewall and the bottom of the via opening; and
forming an interconnect via in the via opening.
